(19) United States
(12) Patent Application Publication
(10) Pub. No.: US 2008/0272426 A1
(43) Pub. Date: Nov. 6, 2008

(54) Nonvolatile Memory Transistors Including Active Pillars and Related Methods and Arrays

(75) Inventors: Soo Doo Chae, Gyeonggi-do (KR); Chung-woo Kim, Gyeonggi-do (KR); Chan-jin Park, Gyeonggi-do (KR); Jeong-hee Han, Gyeonggi-do (KR); Byung-gook Park, Seoul (KR); Gil-seong Lee, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/060,391

(22) Filed: Apr. 1, 2008

(30) Foreign Application Priority Data
Apr. 2, 2007 (KR) 10-2007-0032517

(51) Int. Cl. H01L 29/00; H01L 21/336

(52) U.S. Cl. 257/321; 438/264; 257/E21.409; 257/E29.001

(57) ABSTRACT

Nonvolatile memory transistors including active pillars having smooth side surfaces with an acute inward angle are provided. The transistor has an active pillar having smooth side surfaces with an acute inward angle and protrudes from semiconductor substrate. A gate electrode surrounds the side surfaces of the active pillar. A charge storage layer is provided between the active pillar and the gate electrode. Nonvolatile memory arrays including the transistor and related methods of fabrication are also provided.

### CLAIM OF PRIORITY

This application claims the benefit of Korean Patent Application No. 10-2007-0032517, filed on Apr. 2, 2007, in the Korean Intellectual Property Office, the disclosure of which is incorporated herein in its entirety by reference.

### FIELD OF THE INVENTION

The present invention relates generally to semiconductor devices and, more particularly to, nonvolatile memory transistors, arrays and related methods.

### BACKGROUND OF THE INVENTION

A commonly used type of nonvolatile memory transistor (NVMT) is a planar type transistor. Typically, a planar type transistor has a gate electrode on a semiconductor substrate and junction regions at both sides of the gate electrode. As the integration density of memory devices has increased, problems with such planar type nonvolatile memory transistors may also increase. For example, the channel length of transistors are typically shortened to increase their integration density and shortening the channel length may cause a short channel effect. Furthermore, an increased integration density may lead to an increased number of transistors per unit area, which may also lead to an increase in power consumption.

### SUMMARY OF THE INVENTION

Some embodiments of the present invention provides a nonvolatile memory transistor. The transistor has an active pillar, protruding from semiconductor substrate and having smooth side surfaces with an acute inward angle. A gate electrode surrounds side surfaces of the active pillar. A charge storage layer is provided between the active pillar and the gate electrode.

In further embodiments of the present invention, the active pillar may have an inward angle less then or equal to about 78 degrees with respect to the semiconductor substrate. The active pillar may have an inward angle greater than or equal to about 50 degrees with respect to the semiconductor substrate.

In still further embodiments of the present invention, a drain region is provided in an upper portion of the active pillar and a source region in the semiconductor substrate adjacent to a lower portion of the active pillar.

In some embodiments of the present invention, the charge storage layer may include a charge trapping layer. The nonvolatile memory transistor may further include a tunneling insulation layer between the charge trapping layer and the active pillar and a barrier insulation layer between the charge trapping layer and the gate electrode.

In further embodiments of the present invention, the gate electrode may include a spacer type electrode.

Still further embodiments of the present invention provide nonvolatile memory arrays. The memory arrays have active pillars, protruding from a semiconductor substrate and smooth side surfaces with an acute inward angle. Word lines are extended along each row of the active pillars to surround side surfaces of the active pillars located in each of the rows. Charge storage layers are provided between each of the active pillars and the word lines. Drain regions are located in upper portions of the active pillars. Source regions are located in the semiconductor substrate adjacent to lower portions of the active pillars. Bit lines extend along each column of the active pillars to connect to the drain regions located in each of the columns.

Some embodiments of the present invention provide methods of fabricating nonvolatile memory transistors. The method of fabrication includes forming an active pillar, which protrudes from a semiconductor substrate and has smooth side surfaces with an acute inward angle. A charge storage layer is formed to surround side surfaces of the active pillar. A gate electrode is formed on the charge storage layer.

In some embodiments, the inward angle θ may be controlled by adjusting a flow rate and pressure of an etching gas

### BRIEF DESCRIPTION OF THE DRAWINGS

FIG. 1 is a layout view illustrating a portion of a nonvolatile memory array according to some embodiments of the present invention.

FIGS. 2A through 2M are cross sections taken along a line II-II′ of FIG. 1 and illustrate processing steps in the fabrication of nonvolatile memory arrays illustrated in FIG. 1 according to some embodiments of the present invention.

FIGS. 3A through 3M are cross sections taken along the line III-III′ of FIG. 1 and illustrate processing steps in the fabrication of nonvolatile memory arrays of FIG. 1 in accordance with some embodiments of the present invention.

FIG. 4 is a top view illustrating an active pillar in the nonvolatile memory transistor illustrated in FIG. 3M in accordance with some embodiments of the present invention.

FIG. 5A is a top view of an active pillar shown in FIG. 3M in embodiments where the active pillar is cut along line 4a-4a′ of FIG. 3M.

FIG. 5B is a cross section illustrating a common planar type nonvolatile memory transistor.

FIG. 6A is graph illustrating an electric field along lines a-a′ and b-b′ of the nonvolatile memory transistors illustrated in FIGS. 5A and 5B when a voltage is applied to the gate electrodes.

FIG. 6B illustrates a magnified section 6b of FIG. 6A.

FIG. 7 is a graph illustrating an electric field of a channel region adjacent to a drain region according to an inward angle of an active pillar in the nonvolatile memory transistor illustrated in FIG. 3M and a conventional nonvolatile memory transistor.

FIG. 8A is a graph illustrating program efficiency according to drain current of both the nonvolatile memory transistor illustrated in FIG. 3M and a conventional nonvolatile memory transistor.

FIG. 8B is a graph illustrating a magnified section 8b of FIG. 8A.

### DETAILED DESCRIPTION OF EMBODIMENTS OF THE INVENTION

Embodiments of the invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

Example embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

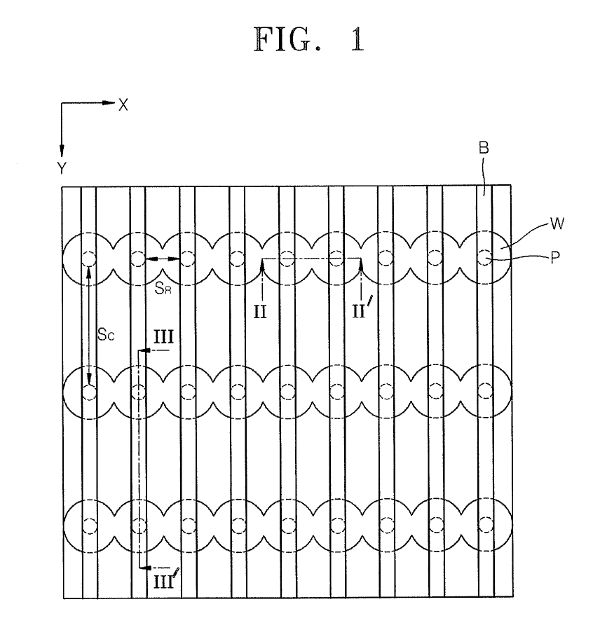

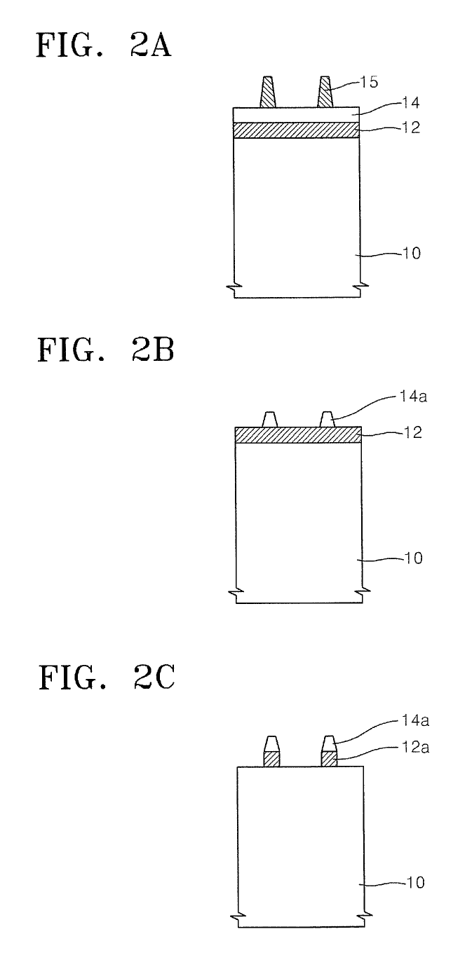

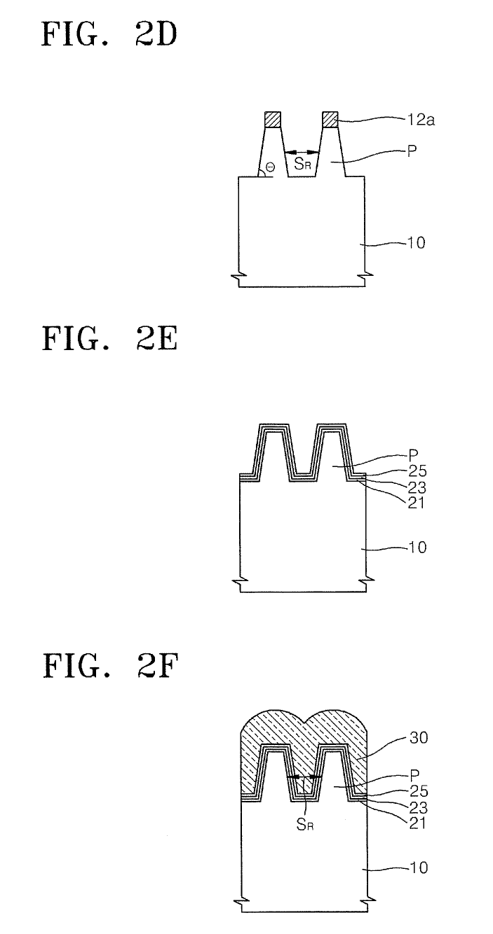

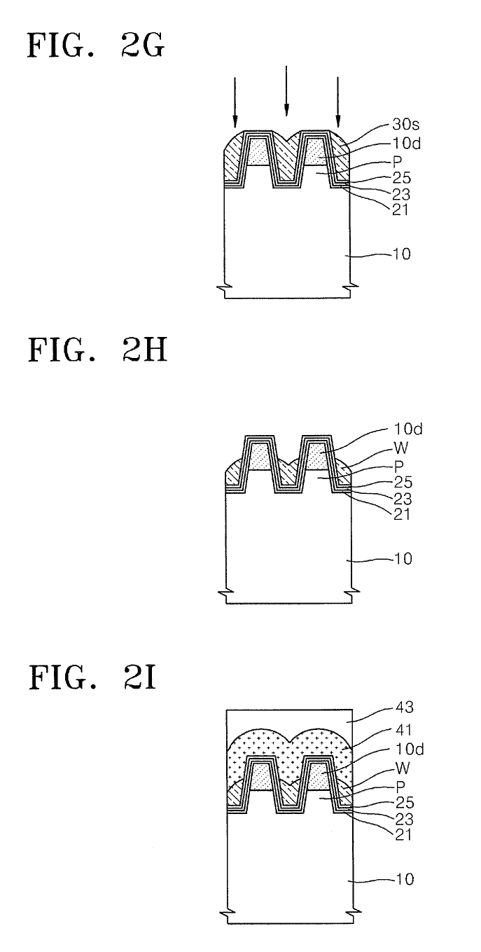

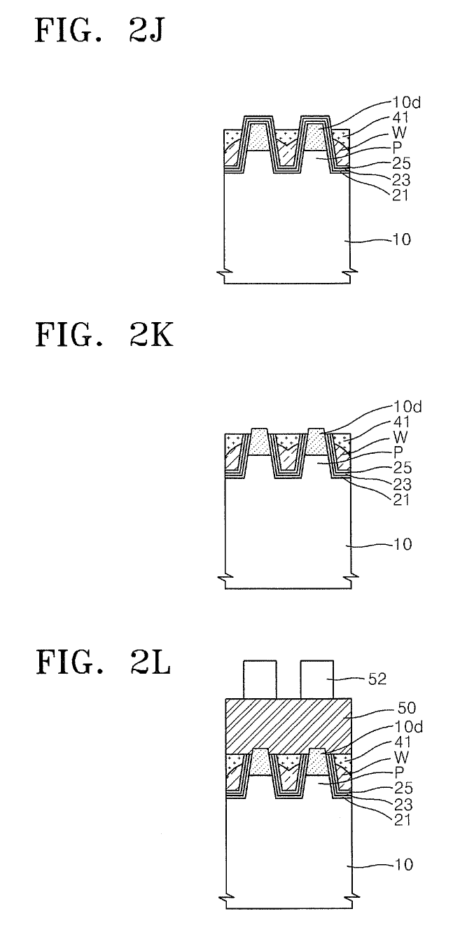

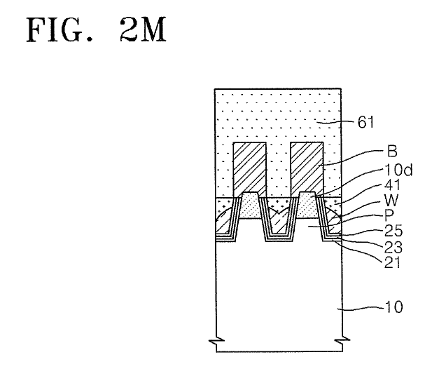

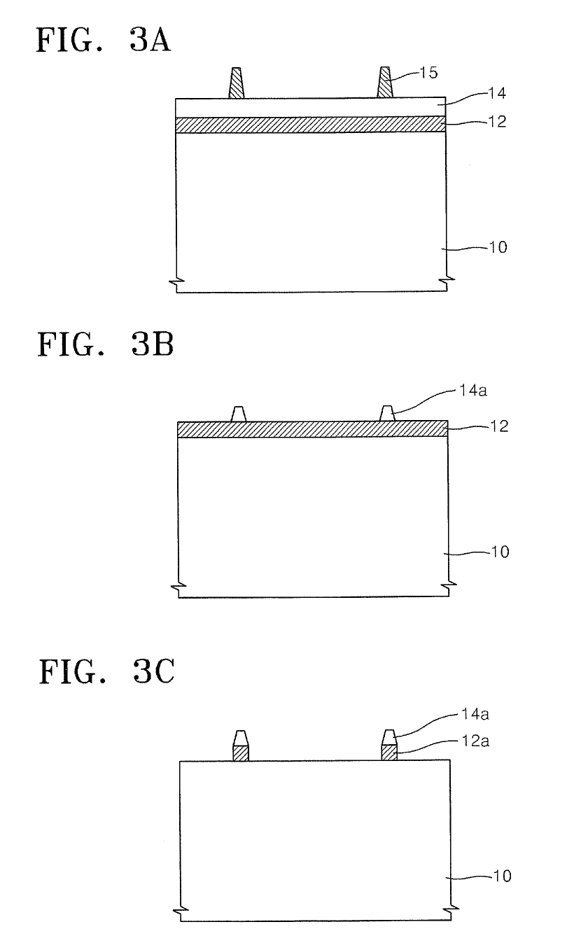

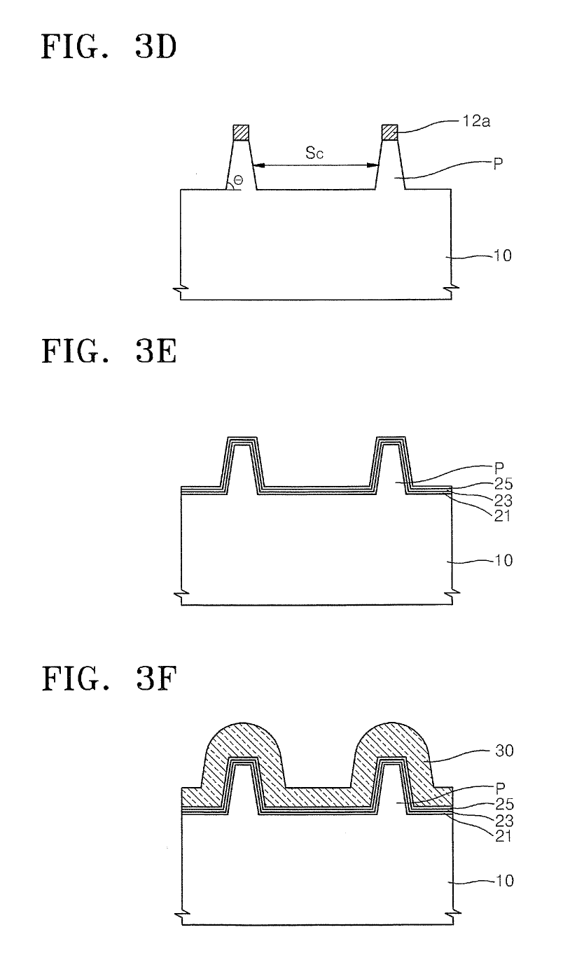

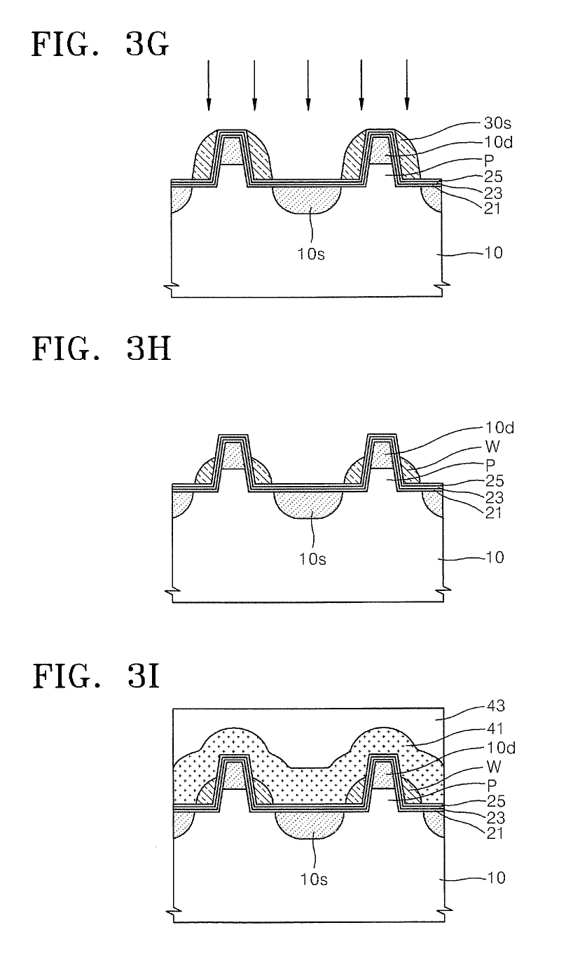

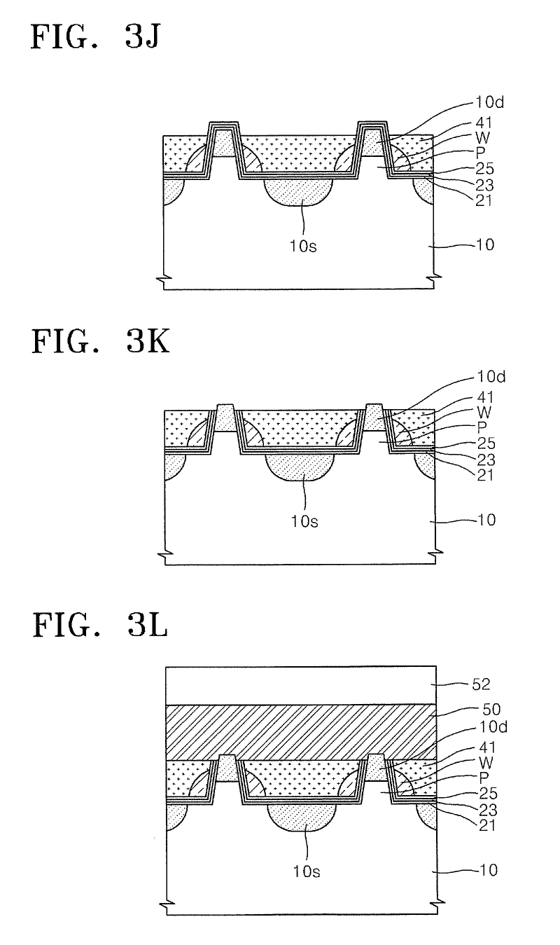

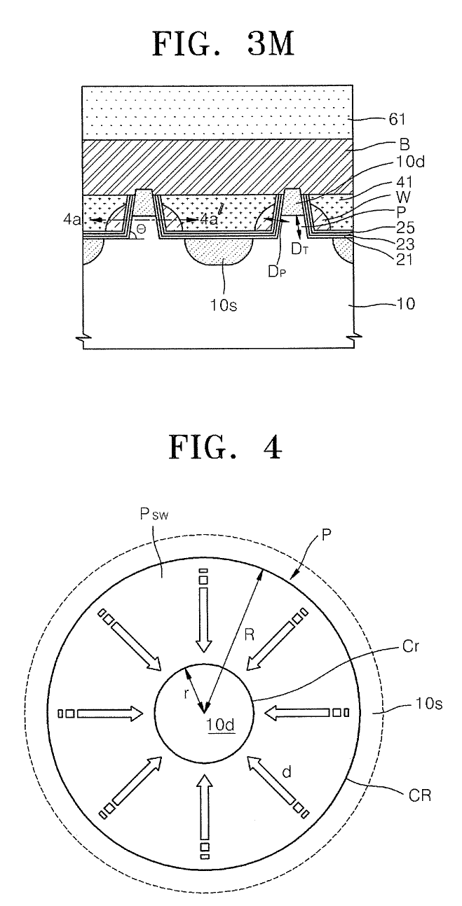

FIG. 1 is a layout view illustrating portions of a nonvolatile memory array according to some embodiments of the present invention, FIGS. 2A through 2M are cross-sections taken along a line II-II′ of FIG. 1 illustrating processing steps in the fabrication of nonvolatile memory arrays of FIG. 1 according to some embodiments of the present invention, and FIGS. 3A through 3M are cross-sections taken along a line III-III′ of FIG. 1 illustrating processing steps in the fabrication of nonvolatile memory arrays of FIG. 1 according to some embodiments of present invention.

Referring first to FIGS. 1, 2A, and 3A, a semiconductor substrate 10 is provided. The semiconductor substrate 10 may be, for example, a silicon single-crystalline substrate or a silicon-on-insulator (SOI) substrate without departing from the scope of the present invention. A hard mask layer 12 is formed on the semiconductor substrate 10. The hard mask layer 12 includes a material having an etching selectivity with respect to the semiconductor substrate 10. The hard mask layer 12 may be, for example, a silicon-oxide layer, a silicon-nitride layer, or a silicon-oxynitride layer. A resist layer is formed on the hard mask layer 12, and resist patterns 15 are formed by patterning the resist layer. The resist layer may be patterned using, for example, electron beam lithography. In some embodiments, the resist layer may be an electron beam resist layer, for example, a hydrogen silsesquioxane (HSQ) layer.

In some embodiments where the resist layer and the hard mask layer 12 are formed of materials with a similar etching selectivity, a protective layer 14 may be additionally formed on the hard mask layer 12 before the resist layer is formed. The protective layer 14 may be, for example, an amorphous silicon layer. The protective layer 14 may be formed, for example, when the resist layer is an HSQ layer in oxide-layer family and the hard mask layer 12 is a silicon oxide layer

Referring now to FIGS. 1, 2B, and 3B, a protective layer 14 is etched using the resist patterns 15 as an etch mask to form protective patterns 14a. The resist patterns 15 are then removed.

Referring now to FIGS. 1, 2C, and 3C, the hard mask layer 12 is etched using the protective patterns 14a as etch masks to form hard mask patterns 12a.

As illustrated in FIGS. 1, 2D, and 3D, the semiconductor substrate 10 is etched selectively using the hard mask patterns 12a as an etch mask to form active pillars P including substrate material. In some embodiments, the protective patterns 14a may include silicon layers. In these embodiments, the protective patterns 14a may be removed simultaneously when etching the semiconductor substrate 10. The active pillars P have smooth side surfaces with an acute inward angle. As illustrated, the active pillars protrude from the semiconductor substrate 10. In other words, the active pillars P may be formed to have a cone shape. Side surfaces of the active pillars P may have inward angles θ of up to about 78 degrees with respect to the surface of the semiconductor substrate. In particular, the inward angles θ may be from about 50 degrees to about 78 degrees.

In some embodiments, the inward angle θ may be controlled by adjusting manufacturing conditions for etching the semiconductor substrate 10. In particular, the inward angle θ may be controlled by adjusting the flow rate and pressure of an etching gas, and platen power, that is, a bias voltage applied to a chuck supporting substrate. In embodiments where the inward angle θ is smaller than 50 degrees, it may be difficult to embody the active pillars P having smooth side surfaces with an acute inward angle even if the manufacturing conditions are adjusted.

The active pillars P are arranged in a matrix. Spaces between the active pillars in each row, i.e., spaces S_{R} between the active pillars in each row, may be narrower than that among the active pillars in each column, i.e., spaces S_{C} among the active pillars in each column.

Referring now to FIGS. 1, 2E, and 3E, the hard mask pattern 12a is removed to expose at least a portion of the active pillars P. A charge storage layer 23 is formed on the exposed active pillars P. In particular, the charge storage layer 23 is formed on the upper and side surfaces of the active pillars P. Therefore, the charge storage layer 23 surrounds side surfaces of the active pillars P as illustrated. In some embodiments, the charge storage layer 23 may be a charge trapping layer. In some embodiments, a tunneling insulation layer 21 may be formed on the active pillars P before the charge trapping layer 23 is formed, and a barrier insulation layer 25 may be formed on the charge trapping layer 23.

The charge trapping layer 23 may be, for example, a silicon nitride-layer or a layer comprising conductive nanocrystal. The conductive nanocrystal may be, for example, metal nanocrystal or semiconductor nanocrystal. The tunneling insulation layer 21 and the barrier insulation layer 25 may be, for example, silicon-oxide layers. In some embodiments of the present invention, the tunneling insulation layer 21 may be a thermal-oxide layer formed using thermal oxidization method. However, embodiments of the present invention are not limited thereto. For example, the tunneling insulation layer 21 may be a deposited-oxide layer without departing from the scope of the present invention.

Referring now to FIGS. 1, 2F, and 3F, a gate conductive layer 30 is formed on the barrier insulation layer 25. The gate conductive layer 30 may be, for example, a poly-silicon layer, doped with either n-type or p-type dopant, or a silicon-germanium layer. The gate conductive layer has a thickness sufficient to fill the space S_{R} among the active pillars. In particular, the thickness of the gate conductive layer 30 may be, for example, at least half of the height of the active pillars P.

Referring now to FIGS. 1, 2G, and 3G, the gate conductive layer is etched back until top surfaces of the active pillars P are exposed. As a result, gate spacers 30s are formed on side surfaces of the active pillars P. The gate spacers 30s surround the side surfaces of the active pillars. While adjacent gate spacers 30s in each row are connected to each other, adjacent gate spacers 30s in each column are separated from each other. Therefore, while the semiconductor substrate 10 is not exposed by spaces between the active pillars P adjacent to each other in each row, the semiconductor substrate 10 is at least partially exposed by spaces between the active pillars P adjacent to each other in each column.

Subsequently, source/drain dopants are implanted into the exposed portion of the semiconductor substrate 10 and upper portions of the active pillars P using the gate spacers 30s as a mask. As a result, source regions 10s aligned with the gate spacers 30s are formed in the semiconductor substrate 10 exposed by space between the adjacent active pillars P in each column. In particular, the source regions 10s are formed in the semiconductor substrate 10 adjacent to lower portions of the active pillars P. Furthermore, drain regions 10d are formed in upper portions of the active pillars P. The source/drain dopants may be n-type dopants, for example, phosphorus (P) or arsenic (As), and may be implanted using any ion implantation method known to those having skill in the art.

Referring now to FIGS. 1, 2H, and 3H, the gate spacers 30s are further etched back. As a result, gate electrodes W surrounding lower portions of the active pillars P are formed, and upper portions of the active pillars P, namely drain regions 10d, are exposed. The adjacent gate electrodes W in each row come in contact with each other and form word lines W. The word lines W are extended in each row of the active pillars P, surrounding lower portions of the active pillars P located in each of the rows.

Referring now to FIGS. 1, 2I, and 3I, an interlayer insulation layer 41 is formed on the semiconductor substrate 10 comprising the gate electrodes W. The interlayer insulation layer 41 may be a TEOS layer. A planarized insulation layer 43 may be formed on the interlayer insulation layer 41. The planarized insulation layer 43 may have a superior planarized characteristic than the interlayer insulation layer 41, and in some embodiments may be, for example, a HSQ layer.

Referring now to FIGS. 1, 2J, and 3J, the planarized insulation layer 43 and interlayer insulation layer 41 are etched to expose at least a portion of the barrier insulation layer 25 formed on upper surfaces of the active pillars P. The method of etching for planarizing may be, for example, an etch-back method or a chemical mechanical polishing method (CMP).

Referring now to FIGS. 1, 2K, and 3K, using the planarized interlayer insulation layer 41 as an etch mask, the barrier insulation layer 25, the charge storage layer 23, and the tunneling insulation layer 21 exposed on upper surfaces of the active pillars P are removed in sequence. As a result, at least a portion of upper surfaces of the active pillars P are exposed.

Referring now to FIGS. 1, 2L, and 3L, a wiring conductive layer 50 is formed on exposed upper surfaces of the active pillars P and the interlayer insulation layer 41. The wiring conductive layer 50 may be, for example, a poly-silicon layer doped with either n-type or p-type dopants. Resist patterns 52 are formed on the wiring conductive layer 50.

Referring now to FIGS. 1, 2M, and 3M, the wiring conductive layer 50 is etched using the resist patterns 52 to form bit lines B connected to upper portions of the active pillars P, namely drain regions 10d. The bit lines B extend in each column of the active pillars P, and are connected to drain regions 10d in the active pillars P located in each of the columns. A second interlayer insulation layer 61 is formed on the bit lines B.

Further embodiments of nonvolatile memory transistors and nonvolatile memory arrays will be discussed with reference to FIGS. 1, 2M, and 3M. Active pillars P are arranged in rows on the semiconductor substrate 10. The active pillars P have smooth side surfaces with an acute inward angle. The active pillars P protrude from the semiconductor substrate 10. The active pillars P may have an inward angle of up to about 78 degrees with respect to the surface of the semiconductor substrate 10. In particular, the active pillars P have an inward angle from about 50 degrees to about 78 degrees with respect to the surface of the semiconductor substrate 10.

Word lines W are disposed along each row of the active pillars P. The word lines W surround the active pillars P located in each of the rows. At this point, the word lines W function as gate electrodes to each of the active pillars P. Therefore, by forming gate electrodes simultaneously when forming the word lines W, contact resistance between the gate electrodes and the word lines, which occurs when the word lines connected to the gate electrodes are formed separately after the gate electrodes are formed, may be reduces or possibly eliminated. The word lines W may surround lower portions of the active pillars P. Furthermore, spacer type word lines W may be formed on the side surfaces of the active pillars P.

Drain regions 10d may be formed in upper portions of the active pillars P. Furthermore, source regions 10s, formed in the semiconductor substrate 10 adjacent to lower portions of the active pillars P, may be formed. In particular, source regions 10s may be formed in the semiconductor substrate 10 exposed between the active pillars adjacent to each other in each column. Moreover, the source regions 10s may function as common source regions for adjacent active pillars P. Regions between each of the drain regions 10d and each of the source regions 10s are defined as channel regions. The channel regions are formed to extend upward from the semiconductor substrate. Accordingly, although the integration density of the device may be increased, the length of the channel region does not have to be shortened. Therefore, the short channel effect may be reduced.

A charge storage layer 23 is provided between each of the active pillars P and each of the word lines W. In some embodiments, the charge storage layer 23 may be a charge trapping layer 23. In some embodiments, a tunneling insulation layer 21 may be provided between the charge trapping layer 23 and the active pillars, and a barrier insulation layer 25 may be provided between the charge trapping layer 23 and the word lines W. Bit lines B are provided along each column of the active pillars P. The bit lines B connect to drain regions 10d located in each of the columns.

FIG. 4 is a top view illustrating an active pillar of the nonvolatile memory transistor illustrated in FIG. 3M. As illustrated in FIG. 4, a radius r of a top surface of an active pillar P where a drain region 10d is formed is smaller than a radius R of a bottom surface of an active pillar adjacent to a source region 10s.

If a positive voltage is applied to the drain region 10d of the active pillar P and a ground voltage is applied to the source region 10s, an electric field ER at the circumference CR of the bottom surface of the active pillar P having the radius R and an electric field Er at the circumference Cr of the upper surface of the active pillar P having the radius r are calculated according to a Gauss's law, and relationships between the electric field ER on the circumference CR of the bottom surface, the electric field Er at the circumference Cr of the upper surface, and the radiuses R and r are expressed according to Equation (1) as follows:

Er:ER=R:r,R>r Equation (1)

Based on Equation (1), it is discovered that the electric field Er at the circumference Cr of the upper surface is greater than the electric field ER at the circumference CR of the bottom surface, when positive voltage and ground voltage to the drain region 10d and source region 10s are applied, respectively. Furthermore, as illustrated in FIG. 3M, the circumferences of horizontal sections may decrease continuously from the bottom surface toward the upper surface in an active pillar P having smooth side surfaces with acute inward angle of semiconductor substrate. Thus, it may be inferred that an electric field on circumference of the horizontal sections of the active pillar, or electric fields on side surface Psw of the active pillar P, continuously increases in a direction d from the bottom surface with larger radius toward the upper surface with smaller radius.

In nonvolatile memory transistors illustrated in FIG. 3M, a channel region is formed on the surface of the side surface Psw of the active pillars P. Accordingly, the electric field on the channel region created on the side surface Psw of the active pillar P increases as approaching to the upper surface, namely drain region 10d. In other words, the electric field on the channel region of the active pillars P is concentrated in region nearby drain region 10d. As a result, electrons, dramatically accelerated by the electric field concentrated in the channel region adjacent to the drain region, may obtain high energy, and it may generate a large number of electron-hole pairs by crashing with lattices. In other words, generation efficiency of channel hot electron (CHE) may be improved by the electric field concentrated in the channel region adjacent to drain region 10d.

To summarize, the electric field on channel regions of the active pillars P having smooth side surfaces with an acute inward angle is concentrated in the region adjacent to the drain region 10d. Thus, generation efficiency of channel hot electron in the channel region adjacent to drain region 10d of the active pillar P may be improved. As a result, program efficiency of a nonvolatile memory transistor including the active pillar may be improved.

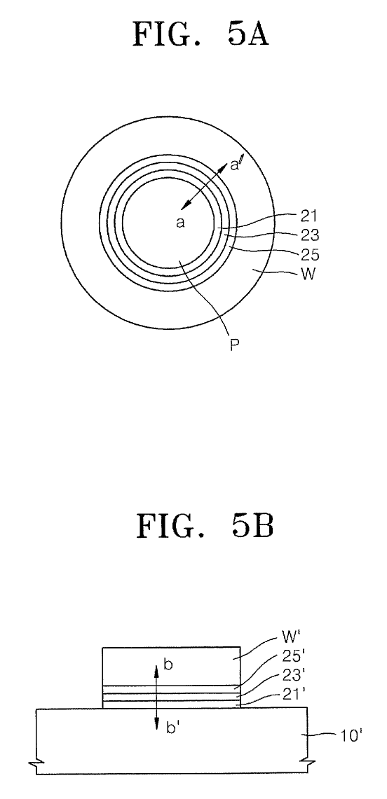

Referring now to FIG. 5A a top view of embodiments where an active pillar is sectioned along the line 4a-4a′ of FIG. 3M. As illustrated in FIG. 5A, an active pillar P is surrounded by a tunneling insulation layer 21, a charge trapping layer 23, a barrier insulation layer 25, and a gate electrode W in sequence. The active pillar P is a single-crystalline silicon pillar, the tunneling insulation layer 21 may be a silicon-oxide layer having a thickness of about 3.0 nm, the charge trapping layer 23 may be a silicon-nitride layer having a thickness of about 5.0 nm, and the barrier insulation layer 25 may be a silicon-oxide layer having a thickness of about 5.0 nm.

Referring now to FIG. 5B, a sectional view illustrating a common planar-type nonvolatile memory transistor according to some embodiments of the present invention will be discussed. Referring now to FIG. 5B, a tunneling insulation layer 21′ which is a silicon-oxide layer having a thickness of about 3.0 nm, a charge trapping layer 23′ which is a silicon-nitride layer having a thickness of about 5.0 nm, a barrier insulation layer 25′ which is a silicon-oxide layer having a thickness of about 5.0 nm, and a gate electrode W′ are located in respective order on a single-crystalline silicon substrate 10′.

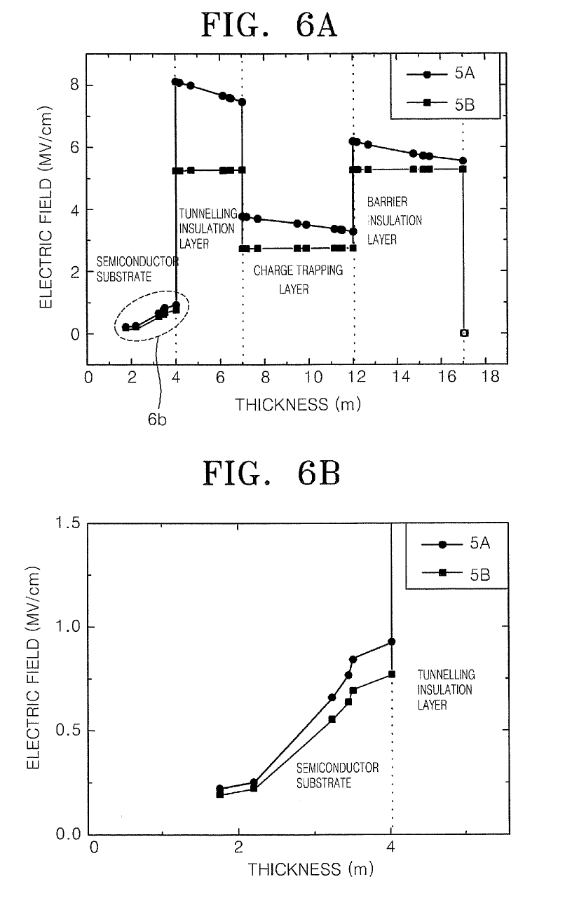

FIG. 6A is a graph showing electric fields along a line a-a′ of FIG. 5A and b-b′ of FIG. 5B when voltage was applied to the gate electrodes of the nonvolatile memory transistors shown in FIGS. 5A and 5B. FIG. 6B is a graph magnifying section 6b of FIG. 6A. A ground voltage is applied to source/drain regions of the nonvolatile memory transistors simultaneously.

Referring to FIGS. 6A and 6B, in comparison to the conventional planar-type nonvolatile memory transistor shown in FIG. 5B, the nonvolatile memory transistor including a cone type active pillar according to some embodiments of the present invention shown in FIG. 5A shows increased electric fields from each layer, namely silicon substrate, tunneling insulation layer, charge trapping layer, and barrier insulation layer. Thus, the transistor according to some embodiments of the present invention shown in FIG. 5A has a greater coupling ratio between gate electrode W and charge trapping layer 23 than the conventional transistor shown in FIG. 5B. Accordingly, since the transistor according to some embodiments of the present invention has a higher injection ratio of hot electrons generated in the channel region into the charge trapping layer 23, program efficiency may be thus improved.

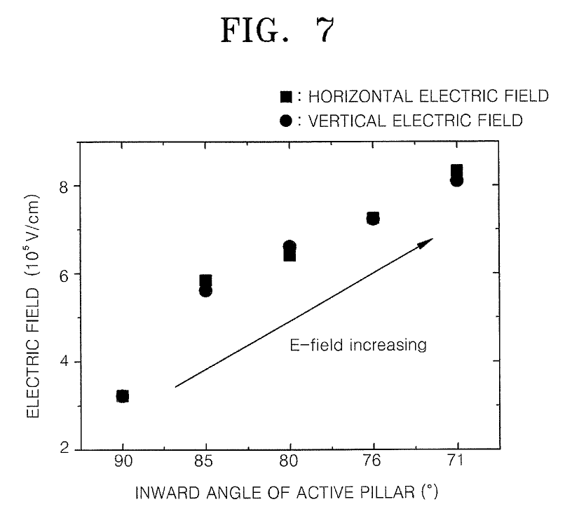

FIG. 7 is a graph of electric field on channel region adjacent to drain region according to the inward angles of active pillars in both nonvolatile memory illustrated in FIG. 3M and conventional nonvolatile memory transistor. In particular, the electric field adjacent to the drain region has been measured by applying 4V to the gate electrodes and the drain regions and 0V to the source regions and the semiconductor substrate. Table 1 below summarizes conditions of transistors shown in FIG. 7.

TABLE 1

| | Inward angle of Active Pillar | | | | |
|---|---|---|---|---|---|
| | 90° | | | | |
| | (for reference) | 85° | 80° | 76° | 71° |
| r/R of Active Pillar wherein | 1 | 0.87 | 0.74 | 0.63 | 0.48 |
| R = 100 nm | | | | | |
| Height of Active Pillar | 150 nm | 150 | 150 | 150 | 150 |
| | | nm | nm | nm | nm |

Note:
R = radius of bottom surface of active pillar,
r = radius of upper surface of active pillar

Referring to FIG. 7 and Table 1, as the inward angle shown as θ in FIG. 3M is smaller, both horizontal electric field ▪ horizontal to channel shown as DT in FIG. 3M and vertical electric field vertical to channel shown as D_{P} in FIG. 3M increase. Generation efficiency of channel hot electron is increasing as the horizontal electric field is increasing, while injection ratio of hot electron generated in channel region into the charge storage layer is increasing as the vertical electric field is increasing. Thus, since a nonvolatile memory transistor includes an active pillar having smooth side surfaces with an acute inward angle, the inward angle of the active pillar is smaller than about 90 degrees, and has higher hot electron generation efficiency and higher injection ratio of generated hot electrons into the charge storage layer, program efficiency may be improved.

A desirable range for the inward angle of active pillar included in nonvolatile memory transistor according to some embodiments of the present invention will be described hereinafter.

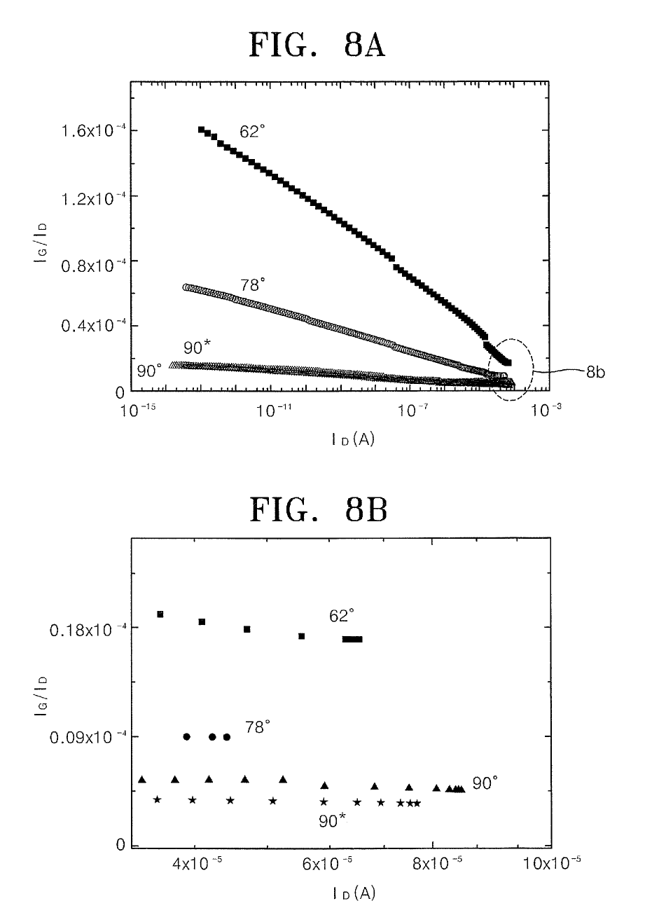

FIG. 8A is a graph showing program efficiency according to drain currents of the nonvolatile memory illustrated in FIG. 3M and conventional nonvolatile memory transistor, and FIG. 8B is a graph magnifying section 8b of FIG. 8A. In particular, 3V were applied to the drain regions and voltages applied to gate electrodes are swept. Table 2 below summarizes conditions of transistors shown in FIG. 8.

TABLE 2

| | Inward angle of Active Pillar | | | |
|---|---|---|---|---|
| | 90° | | | |
| | (for | 90* | | |
| | reference) | (for reference) | 78° | 62° |
| r/R of | 1 wherein | 1 wherein | 0.68 wherein | 0.20 wherein |
| Active Pillar | R = 100 nm, | R = 60 nm, | R = 100 nm, | R = 100 nm, |
| | r = 100 nm | r = 60 nm | r = 68 nm | r = 20 nm |
| Height of | 150 nm | 150 nm | 150 nm | 150 nm |
| Active Pillar | | | | |

Note:
R = radius of bottom surface of active pillar,
r = radius of top surface of active pillar

Referring to FIGS. 8A and 8B and Table 2, as the inward angle of active pillar decreases, the value of gate current over drain current (I_{G}/I_{D}), namely program efficiency, increases. In particular, when the drain current (I_{D}) is 5×10⁻⁵ A, program efficiency improves by two to three times when the inward angle of the active pillar is about 78 degrees in comparison to when the inward angle of active pillar is about 90 degrees, and program efficiency improves by five to seven times when the inward angle of the active pillar is about 62 degrees in comparison to when the inward angle of active pillar is about 90 degrees. Thus, the inward angle of active pillar smaller than about 78 degrees is recommended for program efficiency to be increased by more than two times.

Meanwhile, if the inward angle of active pillar is decreased when height of active pillar and radius R of bottom surface of active pillar is fixed, the radius ratio of active pillar r/R, namely radius r of upper surface of active pillar, may also decrease. Therefore, in order to check out dependency of program efficiency on active pillar's upper surface radius r, program efficiencies for transistors represented as 90 degrees and 78 degrees, those have similar radius r of upper surface of 60 nm and 68 nm, are compared. The transistor represented as 78 degrees, wherein the inward angle of active pillar is 78 degrees, shows much higher program efficiency. Accordingly, it is clear that the program efficiency mainly depends on the inward angle of active pillar rather than on active pillar's upper surface radius r.

As briefly discussed above with respect to FIGS. 1 through 8B, nonvolatile memory transistors including active pillars having smooth side surfaces with an acute inward angle has high generation efficiency of hot electron and high injection ratio of generated hot electron into charge storage layer, thus program efficiency may be improved and power consumption may be lowered consequently. Also, since a channel is formed to extend upward from semiconductor substrate, there is no need to shorten channel length to increase integration density and thus short channel effect may not occur.

While the present invention has been particularly shown and described with reference to exemplary embodiments thereof, it will be understood by those of ordinary skill in the art that various changes in form and details may be made therein without departing from the spirit and scope of the present invention as defined by the following claims.

That which is claimed is:

1. A nonvolatile memory transistor, comprising:
an active pillar protruding from a semiconductor substrate and having smooth side surfaces with an acute inward angle;
a gate electrode surrounding the active pillar; and
a charge storage layer between the active pillar and the gate electrode.

2. The nonvolatile memory transistor of claim 1, wherein the active pillar has an inward angle less then or equal to about 78 degrees with respect to the semiconductor substrate.

3. The nonvolatile memory transistor of claim 2, wherein the active pillar has an inward angle greater than or equal to about 50 degrees with respect to the semiconductor substrate.

4. The nonvolatile memory transistor of claim 1, further comprising a drain region in an upper portion of the active pillar and a source region in the semiconductor substrate adjacent to a lower portion of the active pillar.

5. The nonvolatile memory transistor of claim 1, wherein the charge storage layer comprises a charge trapping layer, and the nonvolatile memory transistor further comprises a tunneling insulation layer between the charge trapping layer and the active pillar and a barrier insulation layer between the charge trapping layer and the gate electrode.

6. The nonvolatile memory transistor of claim 1, wherein the gate electrode comprises a spacer type electrode.

7. A nonvolatile memory array, comprising:
active pillars protruding from a semiconductor substrate and having smooth side surfaces with an acute inward angle;
a word line extended along each row of the active pillars and surrounding side surfaces of the active pillars located in each of the rows;
charge storage layers between each of the active pillars and the word line;
drain regions in upper portions of the active pillars;
source regions formed in the semiconductor substrate adjacent to lower portions of the active pillars; and
bit lines extended along each column of the active pillars to connect drain regions located in each of the columns.

8. The nonvolatile memory array of claim 7, wherein the active pillar has an inward angle less than or equal to about 78 degrees with respect to the semiconductor substrate.

9. The nonvolatile memory array of claim 8, wherein the active pillar has an inward angle greater than or equal to about 50 degrees with respect to the semiconductor substrate.

10. The nonvolatile memory array of claim 7, wherein the charge storage layer comprise a charge trapping layer, and the nonvolatile memory array further comprises a tunneling insulation layer between the charge trapping layer and the active pillar and a barrier insulation layer between the charge trapping layer and the gate electrode.

11. The nonvolatile memory array of claim 7, wherein the word line comprises a spacer type word line.

12. A method of fabricating a nonvolatile memory transistor, comprising:
forming an active pillar protruding from a semiconductor substrate and having smooth side surfaces with an acute inward angle;
forming a charge storage layer surrounding the side surfaces of the active pillar; and
forming a gate electrode on the charge storage layer.

13. The method of claim 12, wherein the active pillar is formed to have inward angles less than or equal to about 78 degrees with respect to the semiconductor substrate.

14. The method of claim 13, wherein the active pillar is formed to have inward angles greater than or equal to 50 percent with respect to the semiconductor substrate.

15. The method of claim 12, wherein the active pillar is formed by selectively etching the semiconductor substrate.

16. The method of claim 12, wherein the charge storage layer comprises a charge trapping layer, the method further comprising forming a tunneling insulation layer on the active pillar before forming the charge trapping layer, and forming a barrier insulation layer on the charge trapping layer after the charge trapping layer is formed.

17. The method of claim 12, wherein the gate electrode is formed by etching back a gate conductive layer after the gate conductive layer is formed on the charge storage layer.

18. The method of claim 12, further comprising forming a drain region in an upper portion of the active pillar and forming a source region in the semiconductor substrate adjacent to lower portion of the active pillar.

19. The method of claim 12, wherein the inward angle θ is controlled by adjusting a flow rate and pressure of an etching gas.
